(19) United States
(12) Patent Application Publication
(10) Pub. No.: US 2008/0308312 A1
(43) Pub. Date: Dec. 18, 2008

(54) CERAMIC ELECTRONIC COMPONENT

(75) Inventors: Izuru SOMA, Tokyo (JP); Naoki CHIDA, Tokyo (JP); Dai MATSUOKA, Tokyo (JP); Miyuki YANAGIDA, Tokyo (JP)

Correspondence Address: OLIFF & BERRIDGE, PLC, P.O. BOX 320850, ALEXANDRIA, VA, 22320-4850, US

(73) Assignee: TDK CORPORATION, Tokyo (JP)

(21) Appl. No.: 12/132,082

(22) Filed: Jun. 3, 2008

(30) Foreign Application Priority Data
Jun. 13, 2007 (JP) 2007-156658

(51) Int. Cl. H05K 1/11

(52) U.S. Cl. 174/261

(57) ABSTRACT

A ceramic electronic component comprises a ceramic element body and an outer electrode arranged on the ceramic element body. The outer electrode includes a first electrode layer and a second electrode layer formed on the first electrode layer. The first electrode layer is formed on an outer surface of the ceramic element body and contains Ag and a glass material. The second electrode layer contains Pt and has a plurality of holes reaching the first electrode layer at respective locations.

### BACKGROUND OF THE INVENTION

1. Field of the Invention

The present invention relates to a ceramic electronic component including a ceramic element body.

2. Related Background Art

Known as a ceramic electronic component is one comprising a ceramic element body and outer electrodes arranged on the ceramic element body (see, for example, Japanese Patent Application Laid-Open No. 2002-246207). In the ceramic electronic component disclosed in Japanese Patent Application Laid-Open No. 2002-246207, the outer electrodes are formed by applying an electrode paste mainly composed of Ag to the ceramic element body and sintering the electrode paste.

### SUMMARY OF THE INVENTION

It is an object of the present invention to provide a ceramic electronic component having an outer electrode which is excellent in solder wettability, solder leach resistance, shock resistance, and connection reliability in thermal cycles.

The inventors conducted diligent studies about outer electrodes which are excellent in solder wettability, solder leach resistance, shock resistance, and connection reliability in thermal cycles and, as a result, have found the following facts.

When an outer electrode is formed by sintering a conductive paste containing metal and glass powders onto a ceramic element body, the glass powder softens and melts to yield a glass material, which forms an area where a glass phase and a metal phase are mixed on the inside of the outer electrode (on the ceramic element body side). In the area where the glass phase and metal phase are mixed, the glass material attached to an outer surface of the ceramic element body functions like an anchor, so as to enhance the connection strength between the ceramic element body and outer electrode, thereby improving the shock resistance.

When the metal powder contained in the conductive paste is constituted by Ag, the outer electrode contains Ag which is easy to wet with solder, whereby the solder wettability improves. However, the outer electrode containing Ag causes so-called solder leach in which Ag contained in the outer electrode elutes into molten solder so that the outer electrode partly disappears, thereby deteriorating the solder leach resistance.

When the metal powder contained in the conductive paste is constituted by Pt, the outer electrode contains Pt which is easy to wet with solder, whereby the solder wettability improves. Pt contained in the outer electrode does not elute into the molten solder, whereby the solder leach resistance also improves. When the outer electrode contains Pt, however, cracks may occur between the solder and outer electrode in thermal cycles, whereby the solder and outer electrode may lose their physical and electric connections and lower the connection reliability.

The following seems to be a reason why cracks occur between the solder and outer electrode. When the solder and outer electrode come into contact with each other, Sn contained in the solder and Pt contained in the outer electrode form an intermetallic compound in the vicinity of the interface between the solder and outer electrode (the junction between the solder and outer electrode). The intermetallic compound formed between Sn and Pt is an intermetallic compound of daltonide type in terms of crystal structure, which is hard and brittle in general. Therefore, cracks may occur at the above-mentioned junction where the Sn—Pt intermetallic compound exists if repetitive stresses caused by a thermal cycle act thereon.

When the solder and outer electrode come into contact with each other in the case where the outer electrode contains Ag instead of Pt, Sn contained in the solder and Ag contained in the outer electrode form an intermetallic compound of Sn and Ag at the above-mentioned junction. This Sn—Ag intermetallic compound is an intermetallic compound of berthollide type, which is soft and ductile in general. This can restrain cracks from occurring at the junction.

The intermetallic compound of Pt and Ag is also an intermetallic compound of berthollide type, which is soft and ductile as with the Sn—Ag intermetallic compound.

In view of the results of studies, the ceramic electronic component in accordance with the present invention comprises a ceramic element body and an outer electrode arranged on the ceramic element body, the outer electrode including a first electrode layer, formed on an outer surface of the ceramic element body, containing Ag and a glass material; and a second electrode layer, formed on the first electrode layer, containing Pt and having a plurality of holes reaching the first electrode layer at respective locations.

Since the first electrode layer of the outer electrode contains the glass material in the ceramic electronic component in accordance with the present invention, the connection strength between the ceramic element body and the outer electrode (first electrode layer) increases, thereby improving the shock resistance. Since the second electrode layer contains Pt, the solder wettability and solder leach resistance of the outer electrode improve.

The second electrode layer is formed with a plurality of holes reaching the first electrode layer at respective locations. Therefore, when solder attached onto the second electrode layer is molten, the molten solder reaches the first electrode layer through the holes formed in the second electrode layer, thereby coming into contact with the first electrode layer. When the solder comes into contact with the first electrode layer, Sn contained in the solder and Ag contained in the first electrode layer form an intermetallic compound therebetween in the vicinity of the interface between the solder and first electrode layer. Therefore, no cracks occur between the solder and outer electrode (first electrode layer) in thermal cycles, whereby the connection reliability of the outer electrode improves.

Since the first and second electrode layers contain Ag and Pt, respectively, an intermetallic compound of Pt and Ag is formed in the vicinity of the interface between the first and second electrode layers in the present invention. Therefore, no cracks occur between the first and second electrode layers in thermal cycles, whereby the connection reliability of the outer electrode improves.

Preferably, the ceramic electronic component further comprises a protruded electrode which is formed on the second electrode layer and made of solder.

Preferably, the ceramic electronic component further comprises an inner electrode, arranged within the ceramic element body, containing Pd and connecting with the first electrode layer, while the first electrode layer further contains Pd.

In the case where the inner electrode and first electrode layer contain Pd and Ag, respectively, the inner electrode extends so as to project greatly from the outer surface of the ceramic element body, since the rate at which Ag diffuses into Pd and the rate at which Pd diffuses into Ag differ from each other. When the inner electrode projects from the outer surface of the ceramic element body as such, there is a fear of the adhesion between the ceramic element body and first electrode layer decreasing, thereby lowering the connection strength between the ceramic element body and first electrode layer. When the first electrode layer contains Pd, in contrast, the inner electrode is restrained from projecting from the outer surface of the ceramic element body, whereby the connection strength between the ceramic element body and first electrode layer can be prevented from decreasing.

Preferably, the first electrode is a sintered electrode layer formed by sintering a conductive paste containing an Ag powder and a glass powder.

Preferably, the second electrode is a sintered electrode layer formed by sintering a conductive paste containing a Pt powder.

The present invention can provide a ceramic electronic component including an outer electrode which is excellent in solder wettability, solder leach resistance, shock resistance, and connection reliability in thermal cycles.

The present invention will become more fully understood from the detailed description given hereinbelow and the accompanying drawings which are given by way of illustration only, and thus are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

FIG. 1 is a perspective view showing the structure of the multilayer chip varistor in accordance with a first embodiment;

FIG. 2 is a perspective view showing the structure of the multilayer chip varistor in accordance with the first embodiment;

FIG. 3 is a view showing a cross-sectional structure taken along the line III-III of FIG. 1;

FIG. 4 is a view showing a cross-sectional structure taken along the line IV-IV of FIG. 3;

FIG. 5 is a view showing a cross-sectional structure taken along the line V-V of FIG. 4;

FIG. 6 is a schematic view for explaining structures of outer and protruded electrodes;

FIG. 7 is a diagram showing an equivalent circuit of the multilayer chip varistor shown in FIG. 1;

FIG. 8 is a flowchart showing a procedure of manufacturing the multilayer chip varistor;

FIG. 9 is a view showing how to manufacture the multilayer chip varistor; and

FIG. 10 is a view showing a cross-sectional structure of the multilayer chip varistor in accordance with a second embodiment.

### DESCRIPTION OF THE PREFERRED EMBODIMENTS

In the following, preferred embodiments of the present invention will be explained in detail with reference to the accompanying drawings. In the explanation, constituents identical to each other or those having the same functions will be referred to with the same numerals or letters while omitting their overlapping descriptions.

### First Embodiment

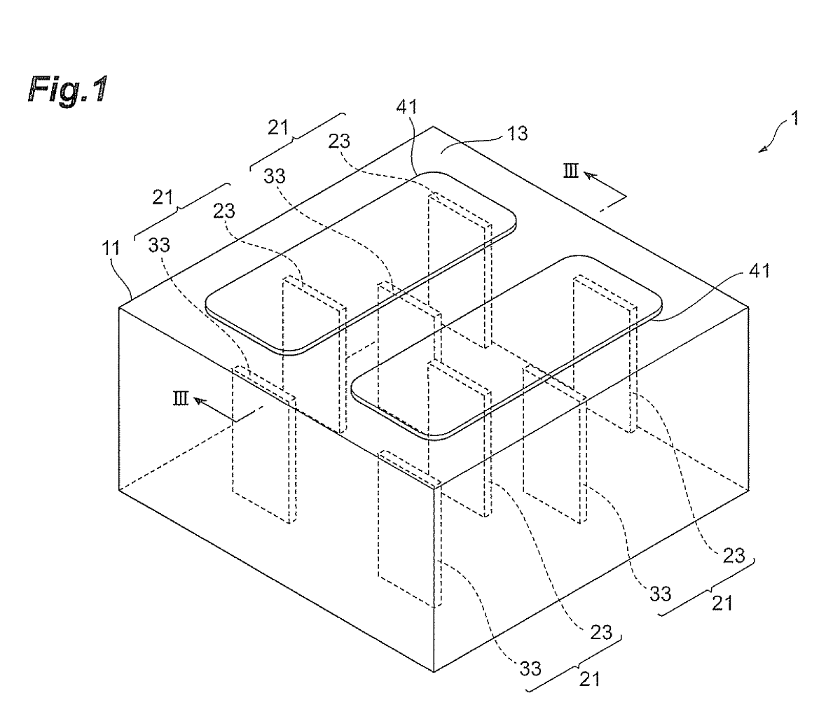

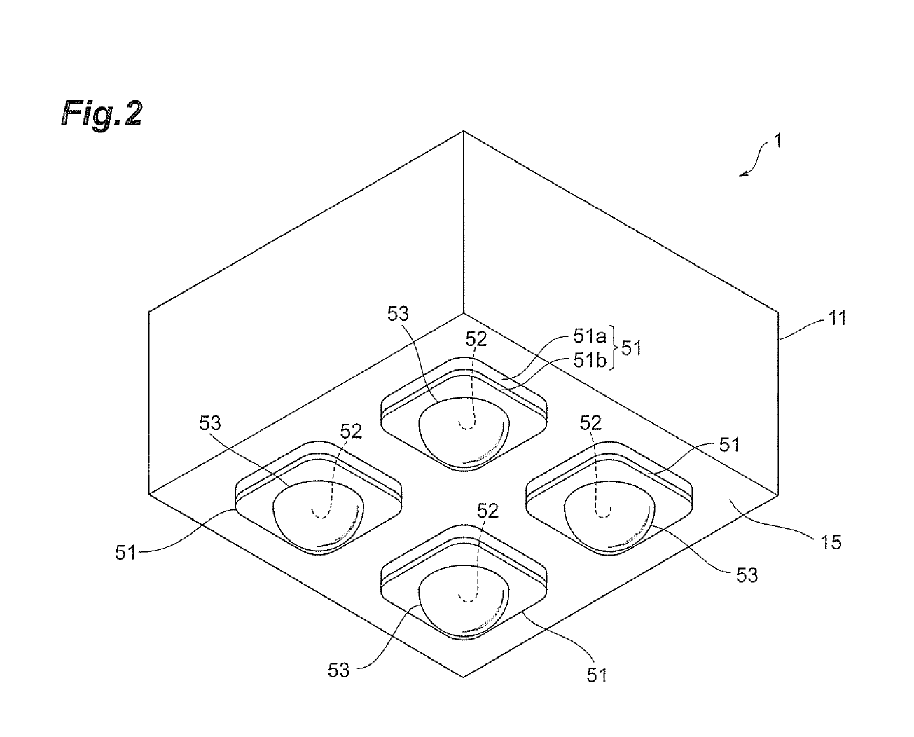

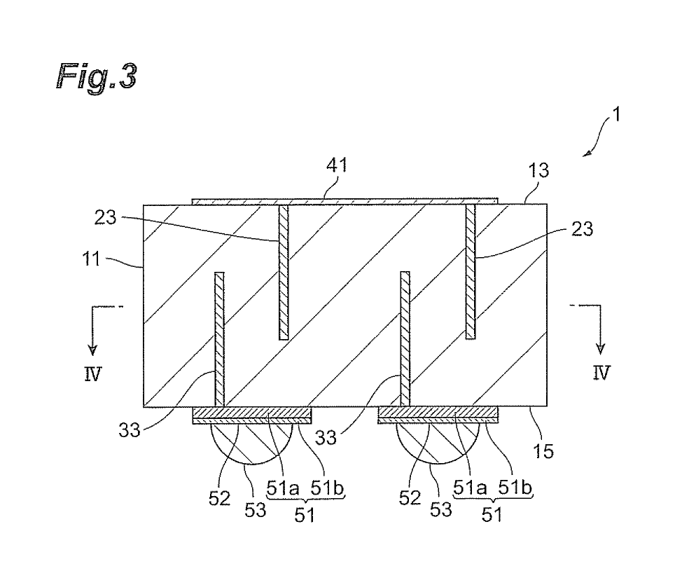

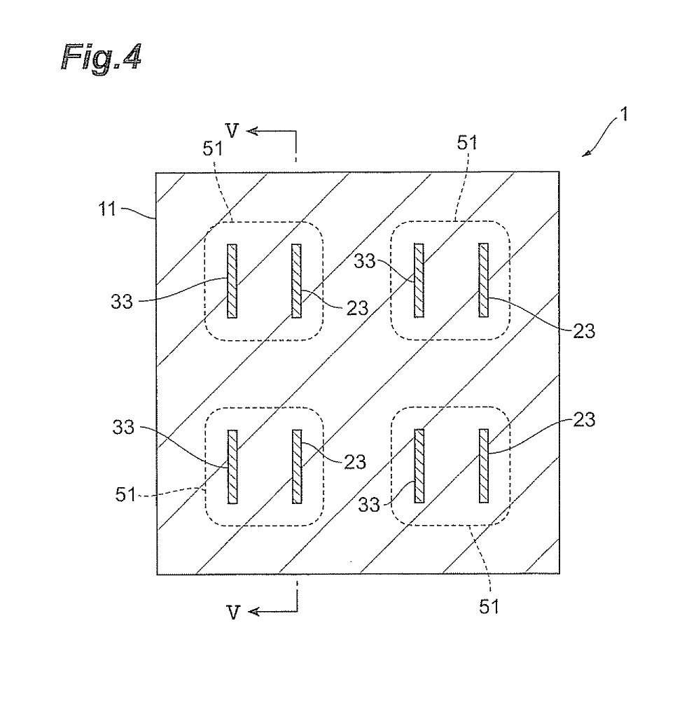

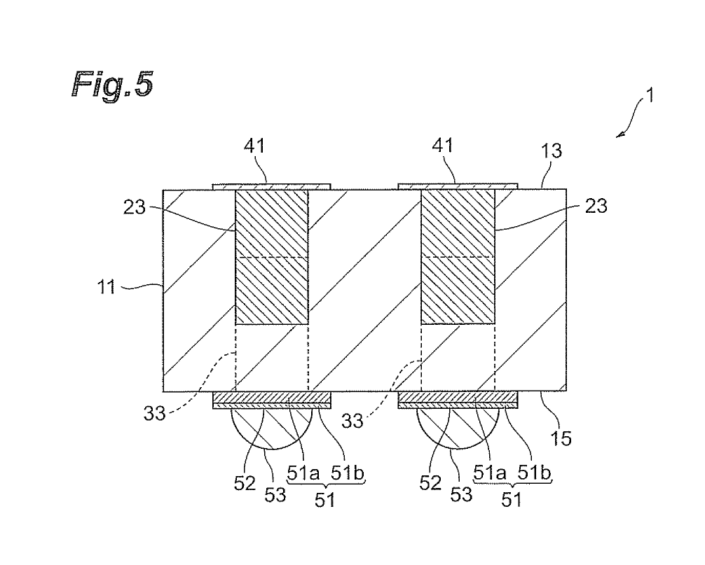

FIGS. 1 and 2 are perspective views showing the structure of the multilayer chip varistor in accordance with the first embodiment. FIG. 3 is a view showing a cross-sectional structure taken along the line III-III of FIG. 1. FIG. 4 is a view showing a cross-sectional structure taken along the line IV-IV of FIG. 3. FIG. 5 is a view showing a cross-sectional structure taken along the line V-V of FIG. 4.

The multilayer chip varistor MV1 shown in FIGS. 1 to 5 is a varistor device of a type adapted to so-called BGA (Ball Grid Array) packages, which is mounted on a mounting board (not depicted) by causing a solder bump provided on the mounting surface side to reflow in order to satisfy demands for high-density mounting of small-size electronic devices such as notebook PCs and cellular phones in particular.

As depicted, the multilayer chip varistor MV1 comprises a varistor element body 11 having a substantially rectangular parallelepiped form, two connecting conductors 41, four outer electrodes 51, and four protruded electrodes 53. The varistor element body 11 has a pair of principal faces 13, 15 opposing each other as outer surfaces. The connecting conductors 41 are arranged on one principal face 13 of the varistor element body 11. The outer electrodes 51 are arranged on the other principal face 15 of the varistor element body 11. The principal face 15 becomes a surface opposing a surface to be mounted with the multilayer chip varistor MV1. In the outer surfaces of the varistor element body 11, the exposed parts surrounding the connecting conductors 41 and outer electrodes 51 are covered with an insulating protective layer (not depicted). The insulating protective layer can be formed by attaching glazed glass (e.g., glass made of SiO₂, ZnO, B, Al₂O₃, and the like) and sintering it at a predetermined temperature.

The varistor element body 11 is constructed as a multilayer body in which a plurality of varistor layers having a nonlinear voltage-current characteristic (hereinafter referred to as “varistor characteristic”) are laminated, while its length, width, and thickness are set to 1 mm, 1 mm, and 0.5 mm, respectively, for example. In the actual multilayer chip varistor MV1, the plurality of varistor layers are integrated to such an extent that their boundaries are indiscernible. The varistor element body 11 is a ceramic device constituted by a semiconductor ceramic.

The varistor layers have a thickness of 5 to 60 μm per layer, for example. The varistor layers are mainly composed of ZnO and contain, as accessory ingredients, Pr which is a rare-earth element and Ca which is an alkaline-earth metal element. The varistor layers also contain Co, Cr, Si, K, and Al, for example, as other accessory ingredients. Though not restricted in particular, the ZnO content in each varistor layer is preferably 69.0 atom % to 99.8 atom % when the total of materials constituting the varistor layer is 100 atom %.

Within the varistor element body 11, four inner electrode pairs 21 are arranged into a matrix of 2×2. Each inner electrode pair 21 is constituted by a first inner electrode 23 and a second inner electrode 33 each having a substantially rectangular form with a thickness of 0.5 to 5 μm, for example. The first inner electrode 23 extends in an in-plane direction. One end of the first inner electrode 23 is exposed at the principal face 13 of the varistor element body 11, while the other end of the first inner electrode 23 is separated by a predetermined distance from the principal face 15 of the varistor element body 11 to the inner side.

The second inner electrode 33 is arranged substantially parallel to the first inner electrode 23. One end of the second inner electrode 33 is exposed at the principal face 15 of the varistor element body 11, while the other end of the second inner electrode 33 is separated by a predetermined distance from the principal face 13 of the varistor element body 11 to the inner side. As shown in FIGS. 3 and 5, the first and second inner electrodes 23, 33 are alternately arranged as seen from a side face of the varistor element body 11, while opposing each other by their substantially half areas.

At least one varistor layer is interposed between the first and second inner electrodes 23, 33, so that the first and second inner electrodes 23, 33 are electrically insulated from each other. The first and second inner electrodes 23, 33 are mainly composed of Pd and contain Ag, for example, as an accessory ingredient.

As shown in FIGS. 1 and 3, each connecting conductor 41 exhibits a substantially rectangular form whose longer and shorter sides have respective lengths of 0.8 mm and 0.4 mm, for example, and is arranged on the principal face 13 side of the varistor element body 11. Each connecting conductor 41 covers portions where the first inner electrodes 23 in its corresponding two inner electrode pairs 21 arranged in a row in the laminating direction of the varistor layers among the four inner electrode pairs 21 are exposed at the principal face 13 of the varistor element body 11. As a consequence, the first inner electrodes 23, 23 are electrically connected to each other through the connecting conductor 41.

The connecting conductors 41 contain metals and a glass material. The connecting conductors 41 contain Ag and Pd as the metals. The connecting conductors 41 are sintered electrode layers formed by sintering a conductive paste containing a metal powder (Ag—Pd alloy powder) and a glass powder. The first electrode layer 51a has a thickness of about 1 to 20 μm, for example.

As shown in FIGS. 2 and 4, the outer electrodes 51, each having a substantially square form with a side length of 0.4 mm, for example, are arranged in a matrix of 2×2 on the principal face 15 side of the varistor element body 11 so as to correspond to the inner electrode pairs 21. Each outer electrode 51 covers a portion where the second inner electrode 33 of its corresponding inner electrode pair 21 is exposed at the principal face 15 of the varistor element body 11. As a consequence, the outer electrodes 51 are electrically connected to their corresponding second inner electrodes 33.

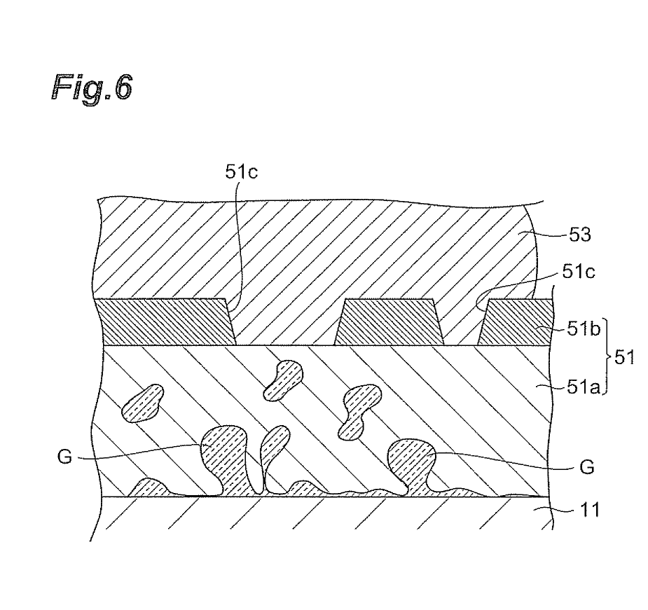

As also shown in FIG. 6, each outer electrode 51 has a first electrode layer 51a and a second electrode layer 51b. FIG. 6 is a schematic view for explaining structures of outer and protruded electrodes.

The first electrode layer 51a is formed on the principal face 15 of the varistor element body 11 and contains metals and a glass material. The first electrode layer 51a contains Ag and Pd as the metals. The first electrode layer 51a is a sintered electrode layer formed by sintering a conductive paste containing a metal powder (Ag—Pd alloy powder) and a glass powder. The first electrode layer 51a has a thickness of about 1 to 20 μm, for example.

The second electrode layer 51b is formed on the first electrode layer 51a and contains Pt. The second electrode layer 51b is a sintered electrode layer formed by sintering a conductive paste containing a Pt powder. The second electrode layer 51b may contain a glass material. The second electrode layer 51b has a plurality of holes 51c reaching the first electrode layer 51a at respective locations. As shown in FIGS. 2 and 3, a substantially center part on the rear side of the second electrode layer 51b is provided with an electrode forming part 52 where a hemispherical protruded electrode 53 is formed. The thickness of the second electrode layer 51b, which is smaller than that of the first electrode layer 51a, is 0.1 to 5 μm, for example. The second electrode layer 51b can be formed not only by sintering the conductive paste but also by vapor deposition or plating.

The protruded electrode 53 is made of solder containing Sn and arranged on the outer electrode 51 (second electrode layer 51b). The protruded electrode 53 is electrically and physically connected to the second electrode layer 51b. The protruded electrode 53 is also electrically and physically connected to the first electrode layer 51a through the holes 51c formed in the second electrode layer 51b. The solder is so-called lead-free solder, examples of which include Sn—Ag—Cu-based solder and Sn—Zn-based solder.

The protruded electrode (so-called bump electrode) 53 can be formed by printing. The protruded electrode 53 can be formed by screen-printing a solder paste onto the electrode forming part 52 of the second electrode layer 51b by using a metal mask formed with an opening corresponding to the electrode forming part 52 of the second electrode layer 51b and then heating and melting the solder paste. Here, the molten solder paste enters the holes 51c formed in the second electrode layer 51b. As a consequence, the protruded electrode 53 and the first electrode layer 51a are connected to each other through the holes 51c. The protruded electrode 53 can be formed not only by printing but also by dispensing, ball mounting, vapor deposition, plating, or the like.

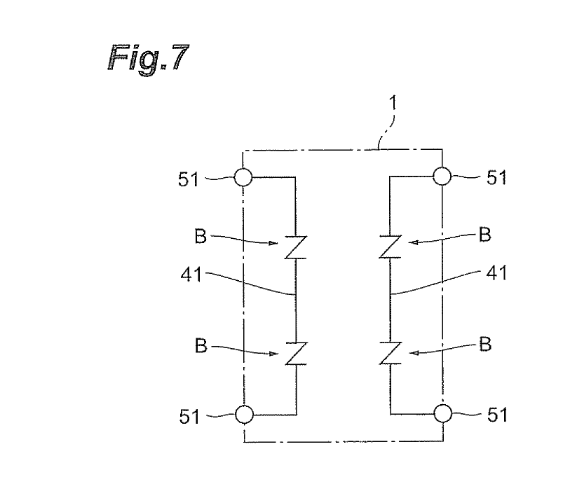

In the above-mentioned multilayer chip varistor MV1, areas where the first inner electrodes 23 oppose their corresponding second inner electrodes 33 in the varistor layers exhibit the varistor characteristic. Therefore, two varistor pairs each constituted by two varistors B connected in series exist in the multilayer varistor MV1 as shown in FIG. 7.

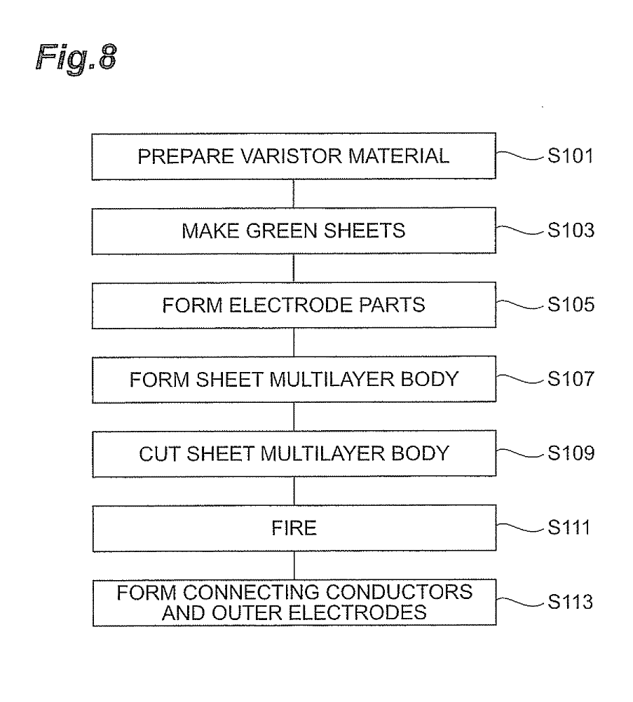

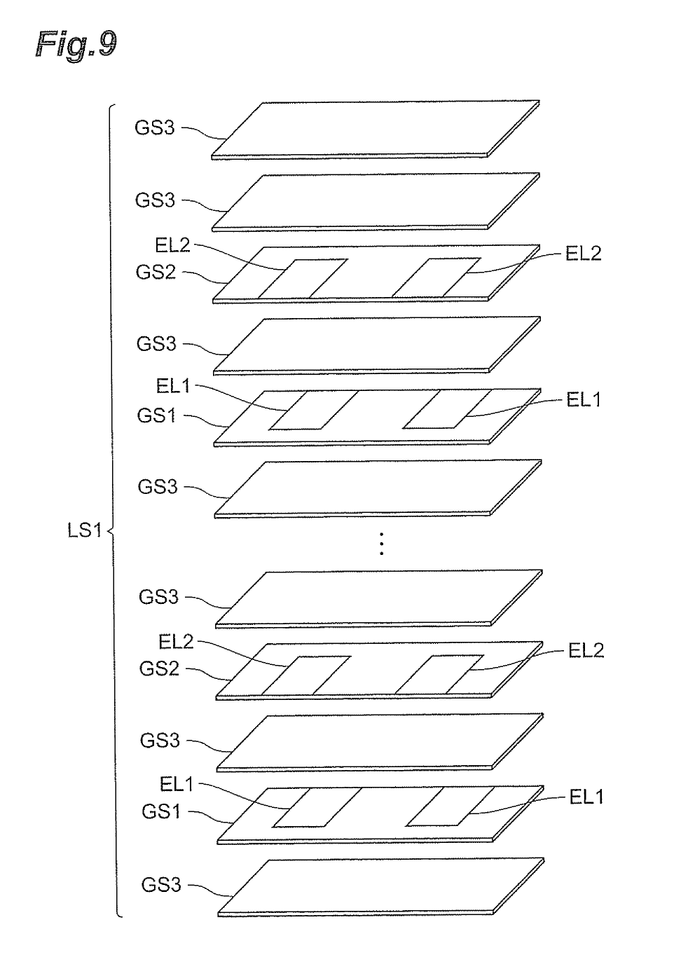

A method of manufacturing the multilayer chip varistor MV1 will now be explained with reference to FIGS. 8 and 9. FIG. 8 is a flowchart showing a procedure of manufacturing the multilayer chip varistor. FIG. 9 is a view showing how to manufacture the multilayer chip varistor.

First, ZnO which is a main ingredient constituting the varistor layers, Pr and Ca which are accessory ingredients, and Co, Cr, Si, K, and Al which are other accessory ingredients are mixed at predetermined ratios, so as to prepare a varistor material (S101). After the preparation, an organic binder, an organic solvent, an organic plasticizer, and the like are added to the varistor material, and they are mixed and pulverized for about 20 hr by using a ball mill or the like, so as to yield a slurry.

Subsequently, the slurry is applied onto a film (not depicted) made of polyethylene terephthalate, for example, by doctor blading, for example, and then dried, so as to form a membrane having a thickness of about 30 μm. Thus obtained membrane is peeled off from the film, whereby a green sheet is obtained (S103).

Next, the green sheet is formed with a plurality of electrode parts corresponding to the first inner electrodes 23 (S105). Similarly, a different green sheet is formed with a plurality of electrode parts corresponding to the second inner electrodes 33 (S105). The electrode parts corresponding to the first and second inner electrodes 23, 33 are formed by printing a conductive paste, in which a metal powder mainly composed of Pd, an organic binder, an organic solvent, and the like are mixed, onto the green sheets by screen printing, for example, and then drying it.

Subsequently, the green sheets formed with the electrode parts and green sheets having no electrode parts are stacked in a predetermined order, so as to form a sheet multilayer body (S 107). Then, the sheet multilayer body is cut into chips, whereby a plurality of divided green bodies LS1 (see FIG. 9) are obtained (S109).

In thus obtained green body LS1, green sheets GS1 formed with electrode parts EL1 corresponding to the first inner electrodes 23 and green sheets GS2 formed with electrode parts EL2 corresponding to the second inner electrodes 33 are alternately laminated while interposing therebetween green sheets GS3 with no electrode parts EL1, EL2. A plurality of green sheets GS3 may be laminated in a row if necessary.

Subsequently, the green body LS1 is heated at a temperature of 180° C. to 400° C. for about 0.5 to 24 hr, for example, so as to effect debindering. Further, the green body LS1 is heated at a temperature of 850° C. to 1400° C. for about 0.5 to 8 hr, for example (S111). The firing turns the green sheets GS1 to GS3 into varistor layers, and the electrode parts EL1, EL2 into the first and second inner electrodes 23, 33, respectively, whereby the varistor element body 11 is obtained.

After the varistor element body 11 is completed, the connecting conductors 41 and outer electrodes 51 are formed on their corresponding principal faces 13, 15 of the varistor element body 11 (S113). Specifically, for forming the connecting conductors 41 and first electrode layers 51a, a conductive paste in which a glass powder, an organic binder, and an organic solvent are mixed in a metal powder containing Pd and Ag (Ag—Pd alloy powder) is initially prepared. Next, thus prepared conductive paste is attached to the principal faces 13, 15 of the varistor element body II by screen printing, for example, and dried. This forms respective conductor parts corresponding to the connecting conductors 41 and first electrode layers 51a. For the glass powder, a glass frit containing at least one of B, Bi, Al, Si, Sr, Ba, Pr, Zn, and Pb can be used.

For forming the second electrode layers 51b, a conductive paste in which an organic binder and an organic solvent are mixed in a metal powder containing Pt (Pt powder) is initially prepared. Next, thus prepared conductive paste is attached onto the first electrode layers 51a by screen printing, for example, and dried. This forms conductor parts corresponding to the second electrode layers 51b.

Thus formed conductor parts are sintered at 900° C., for example, so as to become the connecting conductors 41 and outer electrodes 51 (first and second electrode layers 51a, 51b). Without plating layers such as those of Ni and Sn which have conventionally been formed on the surface of the outer electrode 51, the outer surface of the sintered conductive paste becomes the outer surface of the outer electrode 51 as it is. Thereafter, the protruded electrodes 53 are formed at the electrode forming parts 52 of the outer electrodes 51 by a known method, whereby the above-mentioned multilayer chip varistor MV1 is completed.

When forming the first electrode layer 51a by sintering the conductive paste onto the varistor element body 11, a glass material formed by softening and melting the glass powder contained in the conductive paste forms an area where a glass phase and a metal phase are mixed on the inside of the first electrode layer 51a (on the varistor element body 11 side). In the area where the glass phase and metal phase are mixed, as shown in FIG. 6, a glass material G attached to the outer surface of the varistor element body 11 functions like an anchor, thereby enhancing the connection strength between the varistor element body 11 and first electrode layer 51a.

When forming the second electrode layer 51b by sintering the conductive paste, the holes 51c are formed in the second electrode layer 51b. When sintering the conductive paste, Pt particles are sintered together, so as to form a large mass of Pt, which forms the second electrode layer 51b. Here, the Pt particles attract each other, whereby a plurality of holes 51c are formed such as to be dispersed in the second electrode layer 51b. The state of formation of the holes 51c can be controlled by adjusting the thickness by which the conductive paste is attached, the content of Pt powder, and the like. For example, reducing the thickness by which the conductive paste is attached or the content of Pt powder tends to make it easier to form the holes 51c.

When forming the second electrode layer 51b, Ag contained in the first electrode layer 51a and Pt contained in the second electrode layer 51b form an intermetallic compound in the vicinity of the interface between the first electrode layer 51a and second electrode layer 51b. The Pt—Ag intermetallic compound is an intermetallic compound of berthollide type, which is soft and ductile.

When forming the protruded electrode 53, the solder constituting the protruded electrode 53 and the first electrode layer 51a come into contact with each other through the holes 51c. Here, Ag contained in the first electrode layer 51a and Sn contained in the solder form an intermetallic compound in the vicinity of the interface between the protruded electrode 53 (solder) and the first electrode layer 51a. The Sn—Ag intermetallic compound is an intermetallic compound of berthollide type, which is soft and ductile.

As in the foregoing, the first electrode layer 51a of the outer electrode 51 contains a glass material in the first embodiment, so as to enhance the connection strength between the varistor element body 11 and the first electrode layer 51a (outer electrode 51), thereby improving the shock resistance of the outer electrode 51. Since the second electrode layer 51b in contact with the protruded electrode 53 contains Pt, the solder wettability and solder leach resistance of the outer electrode 51 improve.

Since the second electrode layer 51b is formed with a plurality of holes 51c reaching the first electrode layer 51a at respective locations, the Sn—Ag intermetallic compound is formed in the vicinity of the interface between the solder and the first electrode layer 51a as mentioned above when forming the protruded electrode 53 on the second electrode layer 51b. In a thermal cycle, the Sn—Ag intermetallic compound acts to absorb repetitive stresses caused by the thermal cycle, whereby no cracks occur between the solder and the first electrode layer 51a.

Pt contained in the second electrode layer 51b and Sn contained in the solder form an intermetallic compound in the vicinity of the interface between the second electrode layer 51b and protruded electrode 53. This may cause a fear of cracks occurring between the second electrode layer 51b and the protruded electrode 53 in thermal cycles. However, the solder and the first electrode layer 51a are connected to each other while holding the second electrode layer 51b therebetween. Therefore, even if cracks occur between the second electrode layer 51b and the protruded electrode 53, the solder and the first electrode layer 51a secure a connection therebetween. Hence, the connection reliability of the outer electrode 51 improves in heat cycles.

In the first embodiment, both of the second inner electrode 33 and first electrode layer 51a contain Pd. When the first electrode layer 51a contains Pd, the second inner electrode 33 containing Pd is restrained from projecting from the principal face 15 of the varistor element body 11. This can prevent the connection strength between the varistor element body 11 and first electrode layer 51a from decreasing.

In the first embodiment, the first electrode layer 51 a contains Ag, thereby lowering the resistance of the outer electrode 51.

In the first embodiment, the second electrode layer 51b contains Pt, thereby making it unnecessary to form plating layers. This reduces the number of steps of manufacturing the multilayer chip varistor MV1 and contributes to cutting down the manufacturing cost.

### Second Embodiment

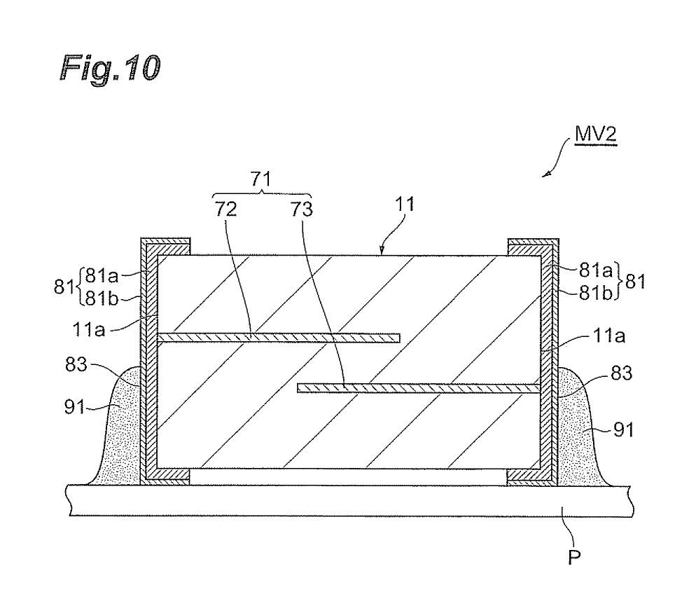

The multilayer chip varistor in accordance with the second embodiment will now be explained. FIG. 10 is a view showing a cross-sectional structure of the multilayer chip varistor in accordance with the second embodiment.

The multilayer chip varistor MV2 shown in FIG. 10 is a multilayer chip varistor of so-called 1608 type whose length, width, and thickness are set to 1.6 mm, 0.8 mm, and 0.8 mm, respectively. The multilayer chip varistor MV2 differs from the multilayer chip varistor MV1 in accordance with the first embodiment mainly in terms of the structure of outer electrodes, but compositions of its constituents and the like are the same as those of the multilayer chip varistor MV1 in accordance with the first embodiment except for the number of inner electrodes arranged and the lack of connecting conductors.

Namely, the multilayer chip varistor MV2 comprises the varistor element body 11, at least one inner electrode pair 71, and a pair of outer electrodes 81. The inner electrode pair 71 is constituted by first and second inner electrodes 72, 73 whose leading end parts oppose each other while at least one varistor layer is interposed therebetween. The first and second inner electrodes 72, 73 are mainly composed of Pd and contain Ag, for example, as an accessory ingredient.

The outer electrodes 81 are arranged so as to cover both end faces 11a of the varistor element body 11, respectively. The outer electrodes 81 are physically and electrically connected to the first and second inner electrodes 72, 73 exposed at their corresponding end faces 11a, respectively. Each outer electrode 81 has a first electrode layer 81a and a second electrode layer 81b as with the outer electrode 51.

The first electrode layer 81a is formed on the end face 11a of the varistor element body 11 and contains metals and a glass material. The first electrode layer 81a contains Ag and Pd as the metals. The first electrode layer 81a is a sintered electrode layer formed by sintering a conductive paste containing a metal powder (Ag—Pd alloy powder) and a glass powder.

The second electrode layer 81b is formed on the first electrode layer 81a and contains Pt. The second electrode layer 81b is a sintered electrode layer formed by sintering a conductive paste containing a Pt powder. The second electrode layer 81b is formed with a plurality of holes reaching the first electrode layer 81a at respective locations. The holes are formed in the second electrode layer 81b as with the holes 51c formed in the second electrode layer 51b, and their state of formation is controlled by adjusting the thickness by which the conductive paste is attached, the content of Pt powder, and the like.

About a half of the area of each outer electrode 81 is a fillet forming area 83. A solder fillet 91 is directly formed at the fillet forming part 83, whereby the multilayer chip varistor MV2 is mounted to a substrate P. Melting and hardening an applied paste forms the solder fillet 91. The solder fillet 91 is electrically and physically connected to the second electrode layer 81b. The solder fillet 91 is made of so-called lead-free solder (e.g., Sn—Ag—Cu-based solder and Sn—Zn-based solder) and contains Sn.

When forming the solder fillet 91, the molten solder paste enters the holes formed in the second electrode layer 81b. As a consequence, the solder fillet 91 and the first electrode layer 81a are electrically and physically connected to each other through the holes formed in the second electrode layer 81b.

As in the foregoing, the first electrode layer 81a of the outer electrode 81 contains a glass material in the second embodiment, so as to enhance the connection strength between the varistor element body 11 and the first electrode layer 81a (outer electrode 81), thereby improving the shock resistance of the outer electrode 81. Since the second electrode layer 81b in contact with the solder fillet 91 contains Pt, the solder wettability and solder leach resistance of the outer electrode 81 improve.

Since the second electrode layer 81b is formed with a plurality of holes 81c reaching the first electrode layer 81 a at respective locations, an intermetallic compound of Sn and Ag is formed in the vicinity of the interface between the solder fillet 91 and the first electrode layer 81a when forming the solder fillet 91. In a thermal cycle, the Sn—Ag intermetallic compound acts to absorb repetitive stresses caused by the thermal cycle, whereby no cracks occur between the solder fillet 91 and the first electrode layer 81a.

Pt contained in the second electrode layer 81b and Sn contained in the solder fillet 91 form an intermetallic compound in the vicinity of the interface between the second electrode layer 81b and solder fillet 91. This may cause a fear of cracks occurring between the second electrode layer 81b and the solder fillet 91 in thermal cycles. However, the solder fillet 91 and the first electrode layer 81a are connected to each other while holding the second electrode layer 81b therebetween. Therefore, even if cracks occur between the second electrode layer 81b and the solder fillet 91, the solder and the first electrode layer 81a secure a connection therebetween. Hence, the connection reliability of the outer electrode 81 improves in heat cycles.

Though the preferred embodiments of the present invention are explained in the foregoing, the present invention is not necessarily restricted to the above-mentioned embodiments, but can be modified in various manners within the scope not deviating from the gist thereof

Though the above-mentioned embodiments explain the multilayer chip varistors as an example of ceramic electronic components, the present invention is not restricted in particular as long as it is a ceramic electronic component having a ceramic element body. For example, the present invention is applicable to electronic components such as multilayer chip capacitors, multilayer actuators, and multilayer chip inductors.

The first electrode layers 51a, 81a contain Pd in the above-mentioned embodiments, but are not always required to do so. Depending on the metal elements contained in the inner electrodes, the first electrode layers 51a, 81a are not required to contain Pd but may contain metals other than Pd.

From the invention thus described, it will be obvious that the invention may be varied in many ways. Such variations are not to be regarded as a departure from the spirit and scope of the invention, and all such modifications as would be obvious to one skilled in the art are intended for inclusion within the scope of the following claims.

What is claimed is:

1. A ceramic electronic component comprising:
a ceramic element body; and
an outer electrode arranged on the ceramic element body;
the outer electrode including:
a first electrode layer, formed on an outer surface of the ceramic element body, containing Ag and a glass material; and
a second electrode layer, formed on the first electrode layer, containing Pt and having a plurality of holes reaching the first electrode layer at respective locations.

2. A ceramic electronic component according to claim 1, further comprising a protruded electrode formed on the second electrode layer and made of solder.

3. A ceramic electronic component according to claim 1, further comprising an inner electrode, arranged within the ceramic element body, containing Pd and connecting with the first electrode layer;
wherein the first electrode layer further containing Pd.

4. A ceramic electronic component according to claim 1, wherein the first electrode is a sintered electrode layer formed by sintering a conductive paste containing an Ag powder and a glass powder.

5. A ceramic electronic component according to claim 1, wherein the second electrode is a sintered electrode layer formed by sintering a conductive paste containing a Pt powder.
